(19) United States
(12) Patent Application Publication
(10) Pub. No.: US 2014/0117527 A1
(43) Pub. Date: May 1, 2014

(54) REDUCED INTEGRATED CIRCUIT PACKAGE LID HEIGHT

(71) Applicant: NVIDIA CORPORATION, Santa Clara, CA (US)

(72) Inventors: Leilei Zhang, Sunnyvale, CA (US); Zuhair Bokharey, Fremont, CA (US)

(73) Assignee: NVIDIA CORPORATION, Santa Clara, CA (US)

(21) Appl. No.: 13/666,846

(22) Filed: Nov. 1, 2012

(51) Int. Cl. H01L 23/12

(52) U.S. Cl. 257/704; 257/E23.003

(57) ABSTRACT

One embodiment of the present invention sets forth an integrated circuit package that includes a substrate, one or more devices mounted on the substrate, and a lid having a top portion and an end portion and configured to encapsulate the one or more devices. The top portion is thinner than the end portion. One advantage of the disclosed design is that the overall height of an IC package may be reduced without significantly impacting the structural integrity or co-planarity of the IC package.

### BACKGROUND OF THE INVENTION

1. Field of the Invention

Embodiments of the present invention relate generally to integrated circuit chip packaging, and, more specifically, to a reduced integrated circuit package lid height.

2. Description of the Related Art

Consumer demand for increasingly smaller electronic devices has grown dramatically, primarily in the form of thinner mobile phones and lighter laptops. Continued miniaturization of consumer electronic devices has generated a demand for thinner integrated circuit (IC) packages that incorporate the processing devices and memory devices that run consumer electronic devices. However, decreasing the overall height of IC packages may compromise the structural integrity of those devices.

As the foregoing illustrates, there is a need in the art for the IC package design that results in a relatively thin IC package while maintaining the structural integrity of the IC package.

### SUMMARY OF THE INVENTION

One embodiment of the present invention sets forth an integrated circuit package. The package includes a substrate, one or more devices mounted on the substrate, and a lid having a top portion and an end portion and configured to encapsulate the one or more devices. The top portion is thinner than the end portion.

One advantage of the disclosed design is that the overall height of an IC package may be reduced without significantly impacting the structural integrity or co-planarity of the IC package.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic cross-sectional view of a conventional IC package system;

FIG. 2 illustrates a cross-sectional view of an IC package having a stamped lid, according to one embodiment of the invention; and

FIG. 3 illustrates a cross-sectional view of an IC package having a forged lid, according to another embodiment of the invention.

### DETAILED DESCRIPTION

In the following description, numerous specific details are set forth to provide a more thorough understanding of the present invention. However, it will be apparent to one of skill in the art that the present invention may be practiced without one or more of these specific details. In other instances, well-known features have not been described in order to avoid obscuring the present invention.

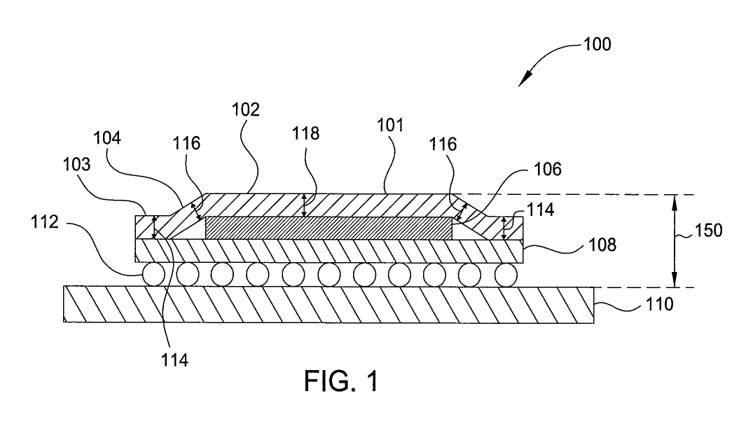

FIG. 1 illustrates a schematic cross-sectional view of a conventional integrated circuit (IC) package 100. As shown, the IC package 100 has an overall height 150 and includes, without limitation, a lid 101 having a top portion 102 with a thickness 118, a middle portion 104 with a thickness 116, and an end portion 103 with a thickness 114, a die 106, and a substrate 108. By way of example and not limitation, in the conventional IC package 100, thicknesses 114, 116 and 118 are approximately the same and may be between 200 and 250 microns (pm). By way of example and not limitation, the die 106 may include one or more devices such as a central processing unit, a graphics processing unit, a memory device, or any combination thereof to form a system-on-chip device. The lid 101 is coupled to the substrate 108 with a lid adhesive filet (not shown) and encapsulates the die 106. The lid 101 is configured to shield and protect the die 106. As also shown, the IC package 100 is coupled to a printed circuit board (PCB) 110 with solder balls 112.

As discussed above, consumer demand has trended towards thinner electronic devices, which, in turn, has increased demand for thinner IC packages. One potential solution to the above problem would be to reduce in a proportional manner the overall thickness of the lid 101 to reduce the height 150 of the IC package 100. Because such a proportional reduction in height would reduce thicknesses 114, 116, and 118 of the lid 101, such a design change would risk reducing the overall stiffness of the IC package 100 and, consequently, reducing the co-planarity of the IC package 100. As a general matter, reduced co-planarity is undesirable because reduced co-planarity could compromise the integrity of the contacts between the IC package, the solder balls and the printed circuit board.

A more preferred approach to reducing the height 150 of the IC package 100 would be to reduce the thickness 118 of the top portion 102, while substantially maintaining thicknesses 114 and 116 of the lid 101. With such an approach, the overall stiffness and co-planarity of the IC package 100 may be substantially retained. Two configurations of an IC package reflecting this design approach are as follows.

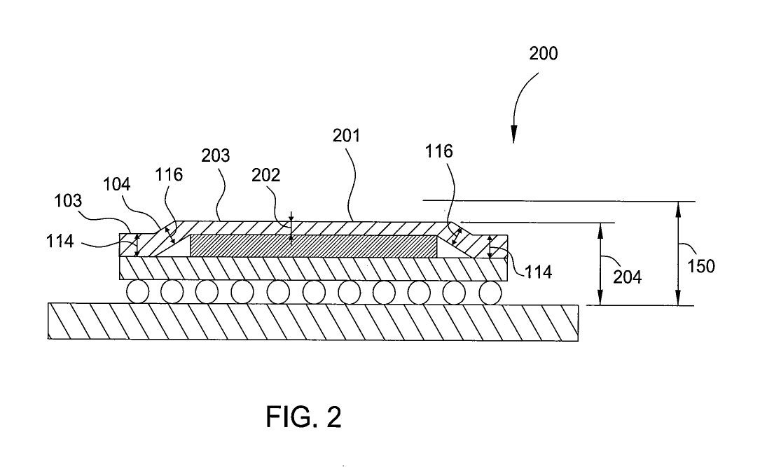

FIG. 2 illustrates a schematic cross-sectional view of an IC package 200 having a stamped lid 201, according to one embodiment of the invention. As shown, the stamped lid 201 has a top portion 203 with a thickness 202, a middle portion 104 with a thickness 116, and an end portion 103 with a thickness 114. In one embodiment, the stamped lid 201 is substantially similar to the lid 101 of FIG. 1, except the thickness 202 of the top portion 203 of the stamped lid 201 is reduced compared to the thickness 118 of the top portion 102 of the lid 101. For example, in one embodiment, thickness 118 may be reduced by at least approximately 50 μm to form thickness 202. And in other embodiments, the minimum of thickness 202 may be approximately 200 μm to approximately 250 μm. In this approach, the thickness of the middle portion 104 of the stamped lid 201 is substantially maintained at thickness 116 relative to the conventional design of the lid 101 of FIG. 1, and the thickness of the end portion 103 of the stamped lid 201 is similarly substantially maintained at thickness 114 relative to the conventional design of the lid 101 of FIG. 1. Maintaining thicknesses 116 and 114 of the middle portion 104 and the end portion 103, respectively, of the stamped lid 201, while reducing the thickness of the top portion 203 of the stamped lid 201 to thickness 202, enables the IC package 200 to have a reduced overall height 204 relative to the overall height 150 of the conventional IC package 100, while maintaining overall stiffness and structural integrity.

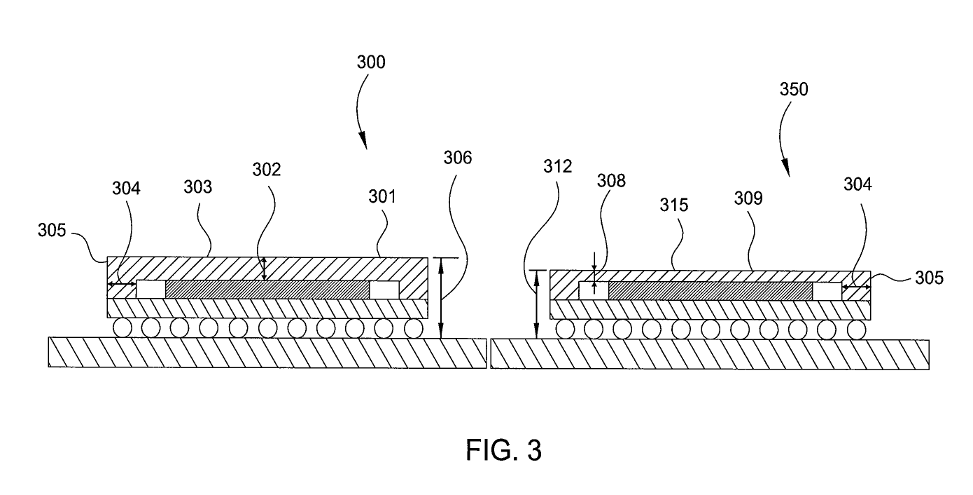

FIG. 3 illustrates a schematic cross-sectional view of both a conventional forged lid IC package 300 and a thin forged lid IC package 350, according to an alternative embodiment of the invention. As shown, the conventional forged lid IC package 300 includes, without limitation, a forged lid 301 that has a top portion 303 with a thickness 302 and an end portion 305 with a thickness 304. As also shown, the conventional forged lid IC package 300 has an overall height 306.

The thin forged lid IC package 350 includes, without limitation, as forged lid 315 that has a top portion 309 with a thickness 308 and an end portion 305 with thickness 304. The thin forged IC package 350 has an overall height 312.

Similar to above, in one embodiment, the forged lid 315 is substantially similar to the forged lid 301, except the thickness 308 of the top portion 309 of the forged lid 315 is reduced compared to the thickness 302 of the top portion 303 of the forged lid 301. For example, in one embodiment, the thickness 302 may be reduced by at least approximately 100 μm to form thickness 308. And in other embodiments, the minimum of thickness 308 may be approximately 100 μm. In this approach, the thickness of the end portion 305 of the forged lid 315 substantially maintained at thickness 304 relative to the conventional design of the forged lid 301. Maintaining thickness 304 of the end portion 305 of the forged lid 315, while reducing the thickness of the top portion 309 of the forged lid 315 to thickness 308, enables the thin forged lid IC package 350 to have a reduced overall height 312 relative to the overall height 306 of the conventional forged lid IC package 300, while maintaining overall stiffness and structural integrity.

Advantageously, the disclosed techniques allow for reduced overall heights of IC packages, which allows for thinner electronic devices. Another advantage of the disclosed techniques is that substantial retention of structural integrity may be substantially maintained despite a decreased overall IC package height. Thus, IC packages fabricated according to the disclosed techniques substantially maintain co-planarity despite having reduced overall heights.

Persons skilled in the art will understand that IC packages designed according to the disclosed techniques may be included and implemented in any type of computing device such as, for example, a cellular telephone, a tablet computer, a handheld computing device, a personal digital assistant, a laptop computer, a desktop computer, or the like.

The invention has been described above with reference to specific embodiments. Persons of ordinary skill in the art, however, will understand that various modifications and changes may be made thereto without departing from the broader spirit and scope of the invention as set forth in the appended claims. The foregoing description and drawings are, accordingly, to be regarded in an illustrative rather than a restrictive sense.

Therefore, the scope of embodiments of the present invention is set forth in the claims that follow.

What is claimed is:

1. An integrated circuit package system, comprising:
a substrate;
one or more devices mounted on the substrate; and
a lid having a top portion and an end portion and configured to encapsulate the one or more devices, wherein the top portion is thinner than the end portion.

2. The system of claim 1, wherein the lid comprises a stamped lid that also includes a middle portion.

3. The system of claim 2, wherein the thickness of the middle portion is substantially similar to the thickness of the end portion.

4. The system of claim 2, wherein the top portion of the lid has a thickness of at least 200 μm.

5. The system of claim 2, wherein the top portion of the lid has a thickness of approximately 200 μm to approximately 250 μm.

6. The system of claim 2, wherein the thickness of the top portion is approximately 50 μm less than the thickness of the middle portion.

7. The system of claim 1, wherein the lid comprises a forged lid.

8. The system of claim 6, wherein the top portion of the lid has a thickness of at least 100 μm.

9. The system of claim 6, wherein the top portion of the lid is at least 50 μm less than the thickness of the end portion.

10. The system of claim 6, wherein the top portion of the lid is between approximately 50 μm and approximately 100 μm less than the thickness of the end portion.

11. The system of claim 1, wherein the one or more devices comprises a graphics processing unit, a central processing unit, or a system-on-chip.

12. A computing device, comprising:
an integrated circuit package system that includes:
a substrate;
one or more devices mounted on the substrate; and
a lid having a top portion and an end portion and configured to encapsulate the one or more devices, wherein the top portion is thinner than the end portion.

13. The computing device of claim 12, wherein the lid comprises a stamped lid, and the thickness of the middle portion is substantially similar to the thickness of the end portion.

14. The computing device of claim 12, wherein the lid comprises a stamped lid, and the top portion of the lid has a thickness of at least 200 μm.

15. The computing device of claim 12, wherein the lid comprises a stamped lid, and the top portion of the lid has a thickness of approximately 200 μm to approximately 250 μm.

16. The computing device of claim 12, wherein the lid comprises a forged lid, and the top portion of the lid has a thickness of at least 100 μm.

17. The computing device of claim 12, wherein the lid comprises a forged lid, and the top portion of the lid is at least 50 μm less than the thickness of the end portion.

18. The computing device of claim 12, wherein the lid comprises a forged lid, and the top portion of the lid is between approximately 50 μm and approximately 100 μm less than the thickness of the end portion.

19. The computing device of claim 12, wherein the one or more devices comprises a graphics processing unit, a central processing unit, or a system-on-chip.
